(19) United States
(12) Patent Application Publication
(10) Pub. No.: US 2004/0171261 A1
(43) Pub. Date: Sep. 2, 2004

(54) Method of etching a silicon nitride film and method of manufacturing a semiconductor device using the same

(76) Inventors: Jong-Heui Song, Suwon-city (KR); Sang-Sup Jeong, Suwon-city (KR); Seung-Min Lee, Sungnam-city (KR)

Correspondence Address: HARNESS, DICKEY & PIERCE, P.L.C., P.O. BOX 8910, RESTON, VA, 20195, US

(21) Appl. No.: 10/785,178

(22) Filed: Feb. 25, 2004

(30) Foreign Application Priority Data
Feb. 28, 2003 (KR) 2003-12772

(51) Int. Cl. H01L 21/76; H01L 21/302; H01L 21/461

(52) U.S. Cl. 438/691; 438/692

(57) ABSTRACT

Disclosed is a method for etching a silicon nitride film, particularly for silicon nitride films formed over a buffer layer including silicon oxide film during the manufacture of semiconductor devices, that provides a silicon nitride to silicon oxide selectivity of at least about 5 while maintaining an acceptable silicon nitride etch rate. The method utilizes a plasma generated from an etching gas composition that includes CH₂F₂ and may optionally include argon and either CF₄ or O₂ that is applied to a silicon nitride film formed a semiconductor substrate while the substrate is heated to a process temperature of at least about 40° C.

### CROSS REFERENCE TO RELATED APPLICATIONS

This application claims priority under 35 U.S.C. § 119 to Korean Pate Application No. 2003-12772, which was filed on Feb. 28, 2003, the contents of which are herein incorporated by reference in their entirety.

### BACKGROUND OF THE INVENTION

1. Field of the Invention

The present invention relates to a method for etching nitride films and a method of manufacturing a semiconductor device using such an etch method. More particularly, the present invention relates to a method of etching a nitride film with high etching selectivity relative to an oxide film, and a method of manufacturing a semiconductor device using such an etch method.

2. Description of the Related Art

As semiconductor manufacturing technology has been developed to produce semiconductor devices having sub-micron dimensions, semiconductor device designs have increasingly included patterns having critical dimensions below about 0.4 μm. Dry etching methods have been widely employed for forming fine patterns because of their ability to produce patterns having generally vertical profiles that correspond closely to the etch mask patterns. In addition to their ability to etch patterns having fine pattern sizing, dry etching methods can be selected to provide improved etching selectivity for an upper film relative to an underlying film.

Dry etching methods may be generally divided into reactive ion etching (RIE) processes and a plasma etching (PE) processes. Recently, the plasma etching process have been more widely employed because patterns may be formed with higher etching selectivity relative to a photoresist mask pattern and a variety of underlying films than corresponding RIE processes.

There is a continuing trend toward reducing both the size of active regions and the spacing between gate structures comprising semiconductor devices in order to produce semiconductor devices having increased integration density and performance. As a result, the alignment margins relative to the active regions and the gate structures may be reduced when forming contact holes necessary to establish electrical connections between an upper conductive pattern and the active region and/or gate electrodes.

In order to avoid the increasing contact alignment issues, self-aligned contact formation processes have been developed. In such self-aligned contact formation processes, contact holes having various dimensions can be formed without having to utilize a mask layer, with its inherent alignment concerns, while still maintaining sufficient processing alignment and spacing margins for the successful manufacture of semiconductor devices. This processing margin may result from the selection of, among other things, the relative sizing and spacing of adjacent structures, the thickness and composition of the insulating layer(s) where the contact holes are formed and/or the dry etching process chemistry and operating conditions.

In a conventional self-aligned contact formation process, a gate oxide film is formed on a substrate on which an active region and a field region are defined. A polysilicon film, a tungsten silicide film and a silicon nitride film are then formed successively on the gate oxide film. The silicon nitride film is patterned and etched using photolithography and etch processes to form a gate mask. The tungsten silicide film and the polysilicon film are then etched using the gate mask as an etching mask to form a gate electrode structure on the substrate. In this process, the gate mask of silicon nitride protects the gate electrode during the subsequent formation of a self-aligned contact hole.

After a second silicon nitride film is formed on the substrate including the gate electrode, the silicon nitride film is anisotropically etched to form gate spacers adjacent the sidewalls of the gate electrode. The silicon nitride of the gate spacers protects the sidewalls of the gate electrode during the subsequent formation of the self-aligned contact hole. Using the gate electrode and the gate spacer as implant masks, an ion implantation process may be utilized to form source/drain regions in the active regions adjacent the gate electrodes.

An etch stop layer, typically a thin silicon nitride layer, is then formed on the resultant structure. After an interlayer insulation film, typically an oxide layer, is formed on the etch stop layer, the interlayer insulation film is etched to expose the etch stop layer using an etch chemistry that is selective for silicon oxide over silicon nitride. The self-aligned contact holes exposing the source/drain regions between the gate electrodes are then formed by etching the exposed portions of the etch stop layer.

In accordance with the self-aligned contact formation process, the substrate may suffer etch damages during both the step of forming the gate electrode and the step of forming the self-aligned contact holes. In particular, when the portion of the silicon nitride film formed between fine pattern structures such as gate electrodes is etched, the silicon nitride film may not uniformly etched. This lack of uniformity is generally attributed to loading effects that may significantly reduce the density of an etchant having a plasma phase as well as the vapor pressure of a reacted product for the silicon nitride film near the fine pattern structures.

When the silicon nitride film is over etched to compensate for the loading effects, the difference in the etching rates between the silicon nitride film, the oxide film, and, the silicon substrate may result in serious damage to the substrate and may also produce contaminants such as CFₓ from the etching gas(es). The damage to the substrate and the presence of contaminants may increase contact resistance and leakage current, thereby compromising the characteristics and performance of the resulting semiconductor device. On the other hand, when the silicon nitride film is not sufficiently etched, the interval between the gate electrodes may decrease and result in non-opened contact holes between the gate electrodes that may also compromise the functionality and performance of the resulting semiconductor device.

Hence, a buffer oxide layer may be formed on gate structures including gate electrodes and gate masks to reduce damage to the substrate during the etching processes used to form the gate spacer and the contact openings when the silicon nitride film is etched with a plasma dry etching process. Generally, the plasma etching processes used to etch silicon nitride films typically utilize an etching gas including a mixture of O₂ and CF₄ or CHF₃. However, such etching gases tend to have a relatively low etching selectivity (a selectivity of about 2) between the silicon nitride film and the silicon oxide film. As a result of this relatively low etching selectivity, there is an increased likelihood that the substrate may be damaged during the plasma etching process.

In order to reduce or prevent damage to the substrate a method of etching a silicon nitride film with higher etching selectivity using methyl difluoride (CH₂F₂) gas has been proposed in U.S. patent application Ser. No. 2002-84254 and Japanese Laid Open Patent Publication No. 2001-203208. However, this method of etching the silicon nitride film, despite improving the selectivity, has a relatively low etch rate because the silicon nitride film is etched at a temperature of below about 30° C.

### SUMMARY OF THE INVENTION

The present invention provides a method of etching a silicon nitride film with improved etching selectivity relative to a silicon oxide film and an improved silicon nitride etch rate.

The present invention also provides a method of manufacturing a semiconductor device employing the improved method of etching a silicon nitride film.

In an exemplary method of etching a silicon nitride film according to the invention, after forming a buffer layer including silicon oxide on a semiconductor substrate, a silicon nitride film is formed on the buffer layer. Then, the silicon nitride film is etched using an etching gas including methyl difluoride, CH₂F₂. Here, the semiconductor substrate is heated to a temperature of above about 40° C. The etching gas may also include methyl tetrafluoride (CF₄) or oxygen (O₂) and may further include an inert gas such as argon (Ar). Preferably, the semiconductor substrate is heated by a temperature of about 60 to about 100° C. Additionally, the semiconductor substrate having the silicon nitride film is loaded on a supporting plate of an etching chamber, and then the semiconductor substrate is heated through the supporting plate. At this time, the silicon nitride film is etched by introducing the etching gas into the etching chamber.

In an exemplary method of manufacturing a semiconductor device according to the invention, after forming a gate insulation film on a semiconductor substrate, a gate structure having a gate electrode and a gate mask is formed on the gate insulation film. A first buffer layer including silicon oxide is formed on the gate structure and on the semiconductor substrate, and then a silicon nitride film is formed on the first buffer layer. The silicon nitride film is etched using an etching gas including CH₂F₂ to form a gate spacer on a sidewall of the gate structure. At this time, the semiconductor substrate is heated to a temperature of above about 40° C. In addition, a second buffer layer is formed on the gate structure, on the gate spacer and on the semiconductor substrate, and an etch stop layer including silicon nitride is formed on the second buffer layer. An interlayer insulation film is formed on the etch stop layer. A region for a contact hole is defined by etching the interlayer insulation film. A portion of the etch stop layer in the region for a contact hole is etched using an etching gas including CH₂F₂ wherein the semiconductor substrate is heated by a temperature of above about 40° C. Finally, a portion of the second buffer layer in the region for a contact hole is removed.

According to the present invention, because a silicon nitride film formed on a semiconductor substrate is etched using an etching gas including CH₂F₂ at a temperature of above about 40° C., the etching rate of the silicon nitride film may be increased relative to the etching rate of a silicon oxide film, whereby the silicon nitride film may be etched five times as rapidly as the silicon oxide film. This improved selectivity is useful for reducing or eliminating damage to the underlying semiconductor substrate during silicon nitride etch processes.

### BRIEF DESCRIPTION OF THE DRAWINGS

The above features and other advantages of the present invention will become more apparent by describing exemplary embodiments in detail thereof with reference to the accompanying drawings, in which:

FIGS. 1A to 1F are cross-sectional views illustrating a method of etching a silicon nitride film and a method of manufacturing a semiconductor device according to an exemplary embodiment of the present invention. These figures are provided for illustrative purposes only and are not, therefore, drawn to scale. The relative sizing and orientation of the various structural elements may have been exaggerated, simplified and/or otherwise modified to improve the clarity of the drawings with respect to the written description and should not be interpreted as unduly limiting the scope of the invention.

### DETAILED DESCRIPTION OF THE EXEMPLARY EMBODIMENTS

Hereinafter, exemplary embodiments of the present invention will be described in detail with reference to the accompanying drawings. In the following drawings, like reference numerals identify similar or identical elements.

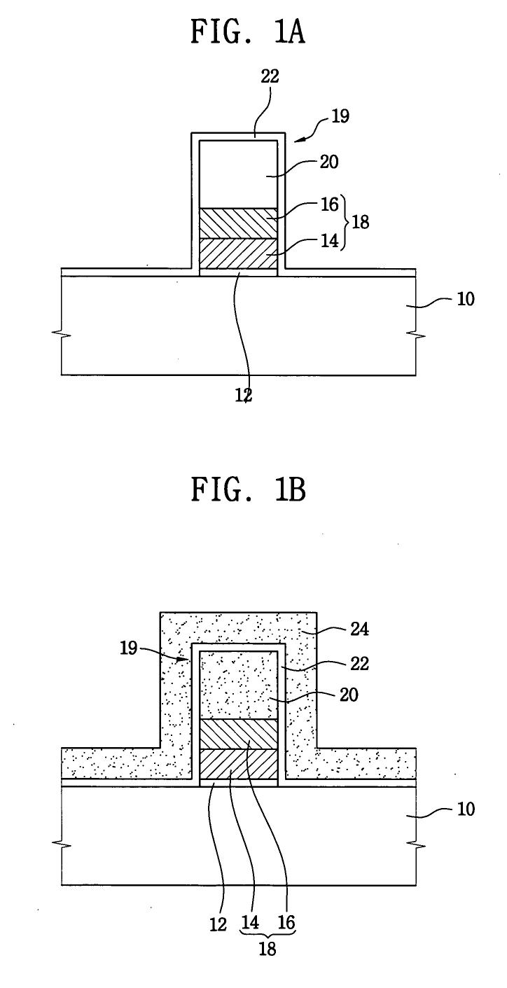

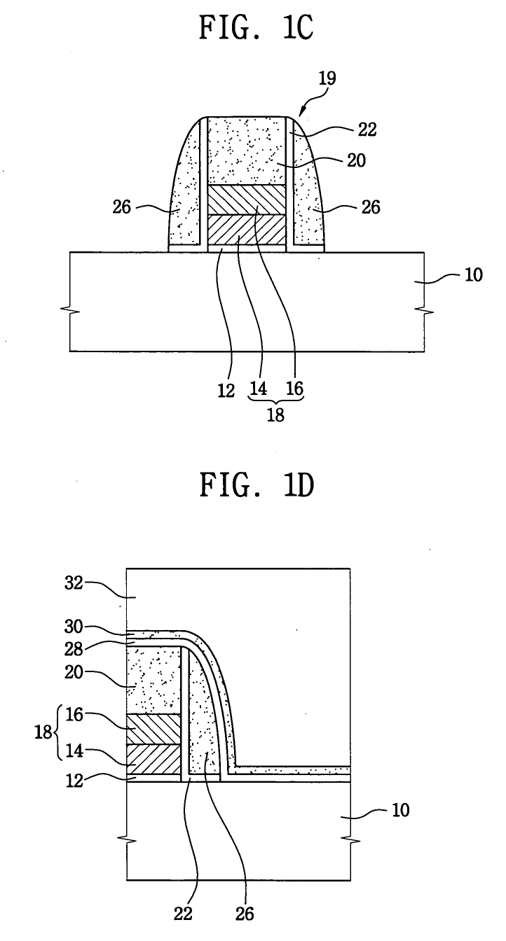

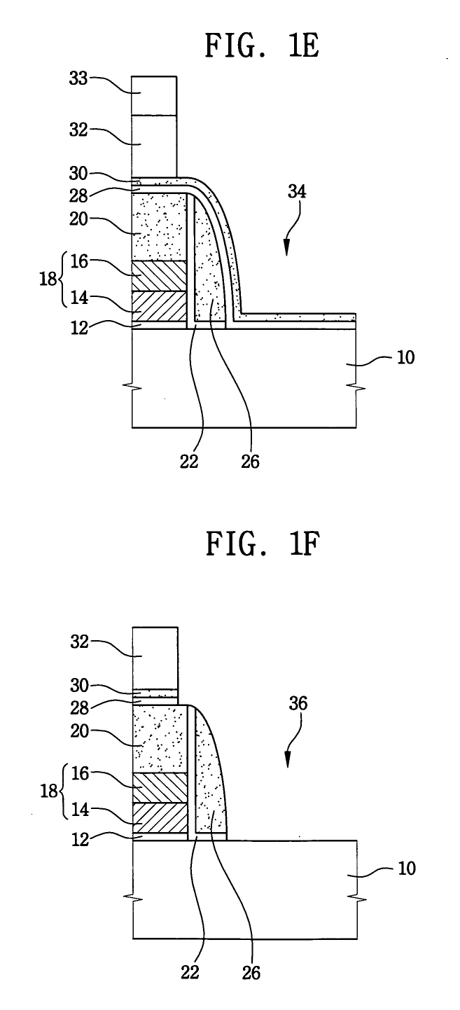

FIG. 1A is a cross-sectional view illustrating a step of forming a first buffer layer 22 on a semiconductor substrate 10. As illustrated in FIG. 1A, a semiconductor substrate 10, such as a silicon wafer, is divided into an active region and a field region by an isolation process such as a shallow trench isolation (STI) process or a local oxidation of silicon (LOCOS) process that forms insulating regions (not shown) between adjacent active regions.

After a gate oxide film 12 is formed in the active region of the semiconductor substrate 10, typically by a thermal oxidation process, a polysilicon film, a metal silicide film and a gate mask layer are successively formed on the gate oxide film 12. The polysilicon film includes polysilicon doped with impurities, and the gate mask layer includes nitride such as silicon nitride. The gate mask layer is patterned using a photolithography process and etched to form a gate mask 20 on the metal silicide film.

Using the gate mask 20 as an etching mask, the metal silicide film and the polysilicon film are then etched to form a stacked gate electrode 18 that includes both a metal silicide film pattern 16 and a polysilicon film pattern 14 on the gate oxide film. The gate mask 20 is left in place to protect the gate electrode 18 during subsequent etching processes used to form the self-aligned contact openings.

A first buffer layer 22 is then formed on the semiconductor substrate 10 on which the gate structure 19, including both the gate electrode 18 and the gate mask 20, is formed. The first buffer layer 22 is typically formed using silicon oxide and is intended to reduce or prevent damage to the semiconductor substrate 10 during a subsequent etching processes used to form a gate spacer 26 (see FIG. 1C).

FIG. 1B is a cross-sectional view illustrating a step of forming a silicon nitride film 24 on the gate structure 19 and on the semiconductor substrate 10. As illustrated in FIG. 1B, the silicon nitride film 24 is then formed on the gate structure 19 and on the remaining portions of semiconductor substrate 10. The silicon nitride film 24 may be formed using a low pressure chemical vapor deposition (LPCVD) process or a plasma enhanced chemical vapor deposition (PECVD) process.

FIG. 1C is a cross-sectional view illustrating a step of forming the gate spacer 26 on the sidewall of the gate structure 19. As illustrated in FIG. 1C, the semiconductor substrate 10 having the silicon nitride film 24 formed thereon as illustrated in FIG. 1B is then transferred into a plasma dry etching apparatus. The semiconductor substrate 10 will typically be loaded onto a supporting plate provided in the reaction chamber of the plasma dry etching apparatus.

In an exemplary apparatus, a cathode composed of aluminum (Al) is disposed within the reaction chamber under the supporting plate, with the plasma etching apparatus being configured to apply radio frequency (RF) power to the cathode with the inner wall of the reaction chamber serving as the corresponding anode.

A heater connected to the supporting plate may be used to heat the semiconductor substrate 10 to a temperature of above about 40° C., and preferably, to a temperature of about 60 to about 100° C. Once the substrate has reached the desired temperature, an etching gas including CH₂F₂ may be introduced into the reaction chamber through a shower head or other gas diffuser positioned over the supporting plate. The etching gas may also include CF₄ or O₂ and may additionally include an inert gas such as argon (Ar) for use as a plasma generating gas and/or a carrier gas.

When the RF power is applied to the cathode and the anode, the etching gas in the reaction chamber is changed into a plasma. The plasma etches the silicon nitride film 24 anisotropically to form the gate spacers 26 adjacent the sidewalls of the gate structure 19. The gate spacers 26 and the gate mask 20 protect the gate electrode 18 during the successive etching processes used for forming the self-aligned contact. When the etching process is carried out using the etching gas including CH₂F₂, the etching rate of the silicon oxide film may be reduced while the etching rate of the silicon nitride film is maintained at a rate similar to that achieved with a conventional etching process using an etching gas including CHF₃. In addition, the conventional etching process is typically performed at a temperature of below about 40° C., while the exemplary etching process of the present invention is performed with semiconductor substrate 10 heated to a temperature above about 40° C. Thus, in the present invention, the silicon nitride film may be etched more rapidly with respect to the silicon oxide film in comparison with the conventional etching process. In addition, when the silicon nitride film is etched using the etching gas containing CH₂F₂ at a temperature above about 40° C., an etching selectivity of more than 5 may be achieved between the silicon nitride and the silicon oxide films while the etching rate of the silicon nitride film is simultaneously increased.

FIG. 1D is a cross-sectional view illustrating steps of forming a second buffer layer 28, an etch stop layer 30 and an interlayer insulation film 32 on the gate spacer 26, on the gate structure 19 and on the semiconductor substrate 10. As illustrated in FIG. 1D, after forming the gate spacer 26, source/drain regions (not shown) are formed at portions of the semiconductor substrate 10 adjacent to the gate structure 19. The source/drain regions are typically formed using an ion implantation process with the gate electrode structure 19 serving as an implant mask. The second buffer layer 28 is formed on the gate spacer 26, on the gate structure 19 and on the semiconductor substrate 10. The second buffer layer 28 is formed using silicon oxide.

The second buffer layer 28 protects the semiconductor substrate 10 from damage during subsequent etching process used to remove the etch stop layer 30. The etch stop layer 30 is formed on the second buffer layer 28, preferably. Using a material having an etching selectivity to the second buffer layer 28 of at least 3. For example, the etch stop layer 30 may be formed using silicon nitride if the second buffer layer 28 is silicon oxide. The interlayer insulation film 32 is then formed on the etch stop layer 30, typically through a CVD process to form a silicon oxide layer.

FIG. 1E is a cross-sectional view illustrating a step of defining a region 34 for a contact hole 36 in the semiconductor substrate 10. As illustrated in FIG. 1E, after a photoresist film (not shown) is formed on the interlayer insulation film 32, the photoresist film is exposed and developed to thereby form a photoresist pattern 33 on the interlayer insulation film 32. Here, the photoresist pattern 33 exposes the region 34 where the contact hole 36 will subsequently be formed. Using the photoresist pattern 33 as an etching mask, the interlayer insulation film 32 is selectively etched using an etching gas that has high etching selectivity of silicon oxide relative to silicon nitride. For example, the etching gas may include one or more CₓF_{y} gases. Thus, the portion of the interlayer insulation film 32 formed in the region 34 for the contact hole 36 is removed.

FIG. 1F is a cross-sectional view illustrating a step of forming the contact hole 36 on the semiconductor substrate 10. As illustrated in FIG. 1F, the photoresist pattern 33 may be removed by an ashing process and/or a wet stripping process, after which the semiconductor substrate 10 is transferred to a plasma dry etching apparatus. After the semiconductor substrate 10 is loaded on the supporting plate of the reaction chamber, the semiconductor substrate 10 is heated to have a temperature of above about 40° C. by the heater connected to the supporting plate. Preferably, the semiconductor substrate 10 is heated to a temperature of about 60 to about 100° C. The etching gas including CH₂F₂ is then introduced into the reaction chamber through a showerhead or other diffuser positioned over the supporting plate on which the semiconductor substrate 10 is loaded. The etching gas preferably includes a mixture of CH₂F₂, CF₄ and O₂. Additionally, an inert gas such as argon may be included in the etching gas as a plasma generating gas and/or a carrier gas. RF power may then be applied to the cathode and the anode to form a plasma from the etching gas in the reaction chamber. The plasma then etches the exposed portion of the etch stop layer 30 in the region 34.

After the etching gas including CH₂F₂ is removed from the reaction chamber, an etching gas for etching silicon oxide is provided into the reaction chamber. The portion of the second buffer layer 28 in the region for the contact hole 36 is removed using the etching gas for etching silicon oxide. As a result, the contact hole or opening 36 to the semiconductor substrate is formed between adjacent gate structures 19 by a self-alignment process. Here, the self-aligned contact hole 36 exposes the portions of the active region corresponding to the source/drain regions.

According to the present invention, because the silicon nitride film formed on a semiconductor substrate is etched using an etching gas including CH₂F₂ at a temperature of above about 40° C., the etching rate of the silicon nitride film may be increased relative to the etching rate of a silicon oxide film. Namely, the silicon nitride film may be etched five times more rapidly than the silicon oxide film. Therefore, the damage to a semiconductor substrate may be prevented during etching the silicon nitride film.

Having described the embodiments of the present invention, it is noted that modifications and variations can be made by persons skilled in the art in light of the above teachings. It is therefore to be understood that changes may be made in the particular embodiment of the present invention disclosed which is within the scope and the spirit of the invention outlined by the appended claims.

What is claimed is:

1. A method of etching a silicon nitride film comprising:
forming a buffer layer of silicon dioxide on a semiconductor substrate;
forming a silicon nitride film on the buffer layer;
heating the semiconductor substrate to a process temperature of at least about 40° C.; and
etching the silicon nitride film using a plasma generated from an etching gas including CH₂F₂, while maintaining the semiconductor substrate at the process temperature.

2. The method of etching a silicon nitride film according to claim 1, wherein:
the etching gas further includes CF₄.

3. The method of etching a silicon nitride film according to claim 1, wherein:
the etching gas further includes argon.

4. The method of etching a silicon nitride film according to claim 1, wherein:
the etching gas further includes O₂.

5. The method of etching a silicon nitride film according to claim 1, wherein:
the etching gas includes a mixture of CH₂F₂, Ar and one gas selected from a group consisting of CF₄ and O₂; and further wherein;
the plasma etches silicon nitride at a first etch rate;
the plasma etches silicon dioxide at a second etch rate; and
a ratio of the first etch rate to the second etch rate is at least 5:1.

6. The method of etching a silicon nitride film according to claim 1, wherein:
the process temperature is between about 60 and about 100° C.

7. The method of etching a silicon nitride film according to claim 1, wherein:
etching the silicon nitride film includes:
loading the semiconductor substrate on which the silicon nitride film has been formed onto a supporting plate within an etching chamber;
heating the semiconductor substrate to the process temperature by heat transfer from the supporting plate; and
introducing the etching gas into the etching chamber and applying RF power to the etching gas to form the plasma within the etching chamber.

8. A method of manufacturing a semiconductor device comprising:
forming a gate insulation film on a semiconductor substrate;
forming a gate structure having a gate electrode and a gate mask on the gate insulation film;
forming a first buffer layer including silicon oxide on the gate structure and on the semiconductor substrate; forming a silicon nitride film on the first buffer layer;
heating the semiconductor substrate to a first processing temperature of at least about 40° C.;
forming a first plasma from a first etching gas including CH₂F₂; and
etching the silicon nitride film using the first plasma to form a gate spacer along a sidewall of the gate structure while maintaining the semiconductor substrate at the first process temperature.

9. The method of manufacturing a semiconductor device according to claim 8, wherein:
the first etching gas further includes CF₄.

10. The method of manufacturing a semiconductor device according to claim 8, wherein:
the first etching gas further includes argon.

11. The method of manufacturing a semiconductor device according to claim 8, wherein:
the first etching gas further includes O₂.

12. The method of manufacturing a semiconductor device according to claim 8, wherein:
the first etching gas includes a mixture of CH₂F₂, Ar and one gas selected from a group consisting of CF₄ and O₂; and further wherein;
the first plasma etches silicon nitride at a first etch rate;
the first plasma etches silicon dioxide at a second etch rate; and
a ratio of the first etch rate to the second etch rate is at least 5:1.

13. The method of manufacturing a semiconductor device according to claim 8, further comprising:
forming a second buffer layer on the gate structure, the gate spacer and the semiconductor substrate, the second buffer layer including silicon oxide;
forming an etch stop layer on the second buffer layer, the etch stop layer including silicon nitride;
forming an interlayer insulation film on the etch stop layer;
removing the interlayer insulation film from a contact hole region, thereby exposing a region of the etch stop layer;
heating the semiconductor substrate to a second process temperature of at least about 40° C.;
removing the exposed region of the etch stop layer with a second plasma generated from a second etching gas that includes CH₂F₂ while maintaining the semiconductor substrate at the second process temperature thereby exposing a region of the second buffer layer; and
removing the exposed portion of the second buffer layer to expose a region of the semiconductor substrate and form a contact opening.

14. The method of manufacturing a semiconductor device according to claim 13, wherein:
the second etching gas includes a mixture of CH₂F₂, Ar and one gas selected from a group consisting of CF₄ and O₂; and further wherein;
the second plasma etches silicon nitride at a third etch rate;
the second plasma etches silicon dioxide at a fourth etch rate; and
a ratio of the third etch rate to the fourth etch rate is at least 5:1.

15. The method of manufacturing a semiconductor device according to claim 14, wherein:
the first etching gas and the second etching gas include substantially the same mixture of CH₂F₂, Ar and one gas selected from a group consisting of CF₄ and O₂.

16. The method of manufacturing a semiconductor device according to claim 14, wherein:
at least one of the first process temperature and the second process temperature is at least about 60° C.

17. The method of manufacturing a semiconductor device according to claim 14, wherein:
both the first process temperature and the second process temperature are at least about 60° C.

18. A method of manufacturing a semiconductor device comprising:
forming a gate insulation film on a semiconductor substrate;
forming a gate structure having a gate electrode and a gate mask on the gate insulation film;
forming a first buffer layer including silicon oxide on the gate structure and on the semiconductor substrate;
forming a silicon nitride film on the first buffer layer;
etching the silicon nitride using an etch method according to claim 1 to form a gate spacer along a sidewall of the gate structure;
forming a second buffer layer on the gate structure, the gate spacer and the semiconductor substrate, the second buffer layer including silicon oxide;
forming an etch stop layer on the second buffer layer, the etch stop layer including silicon nitride;
forming an interlayer insulation film on the etch stop layer;
removing the interlayer insulation film from a contact hole region, thereby exposing a region of the etch stop layer;
etching the exposed region of the etch stop layer using an etch method according to claim 1 to expose a region of the second buffer layer; and
removing the exposed portion of the second buffer layer to expose a region of the semiconductor substrate and form a contact opening.
